(19) United States
(12) Patent Application Publication
(10) Pub. No.: US 2009/0000773 A1
(43) Pub. Date: Jan. 1, 2009

(54) Integrated cooling system

(76) Inventor: Yeshayahou Levy, Haifa (IL)

Correspondence Address: COHEN, PONTANI, LIEBERMAN & PAVANE LLP, 551 FIFTH AVENUE, SUITE 1210, NEW YORK, NY, 10176, US

(21) Appl. No.: 12/231,133

(22) Filed: Aug. 28, 2008

Related U.S. Application Data
(63) Continuation of application No. PCT/IL2007/000252, filed on Feb. 27, 2007.

(30) Foreign Application Priority Data
Feb. 28, 2006 (IL) 173991

(51) Int. Cl. F28D 15/00; H05K 7/20

(52) U.S. Cl. 165/104.34; 361/691

(57) ABSTRACT

A system and a method for implementing a cooling apparatus coupled to and configured for cooling a heat-generating device by coupling a cooling gas driver to the cooling apparatus. The cooling apparatus has an upstream cooling chamber closed downstream by a permeable partition through which the cooling gas flows. The cooling gas driver is configured as a centralized or a distributed gas driving facility dedicated to provide a flow of treated cooling gas, such as air, at a high-differential pressure through the cooling apparatus, the cooling gas driver using minimal energy being disposed remote from the cooling apparatus and from the heat generating device. Implementation is achieved by selecting appropriate governing parameters for the cooling apparatus, the partition, and the cooling gas driver, and by computing mutual matching for optimal cooling operation by absorbing heat from and transferring heat away from the heat-generating device.

### RELATED APPLICATIONS

This application is a Continuation of PCT/IL2007/000252 filed Feb. 27, 2007.

This application claims the priority of Israeli patent application no. 173991 filed Feb. 28, 2006, the content of which is hereby incorporated by reference.

### FIELD OF THE INVENTION

The present invention is related to a method for implementing a cooling system and with a cooling system for cooling a heat-generating device, and in particular with a high differential pressure centralized or distributed cooling gas driver operating in matching association with a cooling apparatus.

### BACKGROUND OF THE INVENTION

The cooling of electronic components, and especially the cooling of the central processing unit(s) of a Personal Computer is known to represent an increasingly difficult problem. Components that generate substantial heat, including electronic and non-electronic components, among which central processing units are currently the most numerous, are referred to hereinbelow as heat generating devices.

Nowadays, the heat generated by heat generating devices cannot longer be removed as was the practice in the past, by the passive combination of conduction, natural convection, and radiation. Rather, fans dedicated to a heat-generating device, and other apparatus are required for the removal of that heat.

It is well known that the heat removal capacity of a coolant depends on several parameters, including the velocity and the density of the coolant and on the difference between the flow recovery temperature and the cooled surface temperature. It is also known that during compression the total temperature of gases such as air rises to temperatures that may exceed the maximum working temperatures of a heat generating device, and therefore the compressed ambient air must usually be cooled down if needed for cooling the heat generating device.

Many methods, systems, and devices for cooling heat-generating devices are known, the most common of which use a fan mounted on top of a heat generating device, or on top of a heat sink attached to the heat generating device. The over-pressure generated by such a fan is typically 100 Pascals (0.001 atm. or 0.001 bar) or even lower. The typical pressure ratio generated by fans is thus in the range of about 1.001:1.

Therefore, the air velocities and the air mass fluxes emanating from fans are relatively low, thereby limiting the heat removal capacity of fans. Together therewith, the temperature rise of air passing through a fan is negligible.

Fans also suffer from another drawback: they catch dust and other flying debris and, unless cleaned regularly, get clogged and eventually stop functioning.

A device for the removal of heat is disclosed in US Patent Application No. 2006/0021364, by Shimada, Tetsuya et al., the device having a cooling apparatus featuring a multiplicity of cooling members and using both an air supply and a compressed air supply.

US Patent Application No. 2003/0168202 by Kumrath discloses “a flow field based cooler for a CPU. The cooler comprises a cooling base having an array of recess on its top surface. The cooling base is secured on the CPU above which a substantially similar sized orifice plate, having an array of orifices each corresponding to the recess is attached. A tab at each side of the cooling base is used to clamp the orifice plate and the cooling base with a predetermined separation distance. An electrical fan above the cooling base and the orifice plate is enclosed therein and secured on the CPU. When the fan is operative to provide the required coolant mass flow, the impinging jets are generated through the orifice plate and directed toward the recesses within which the turbulence and vorticity of wall-jet flow are enhanced, thereby dissipating the heat flux generated from the running CPU.” This is again a fan-cooled device.

The hereinabove cited applications and other patents use fans or blowers, which usually provide low pressure and fairly low air velocities, or else require a multiplicity of cooling members and two different flows of air. Another feature of most of the prior art designs is that the slightly pressurized air flow leaving the fan reaches the surface to be cooled without any further treatment or conditioning.

Many electronic and other devices present a problem to designers by incorporating small heat generating devices that are tightly packaged together in a reduced-size housing and need to be cooled to controlled temperature levels. However, it does not seem possible to implement small and efficient cooling devices for attachment to the heat generating devices within a cramped housing.

### SUMMARY OF THE INVENTION

One object of the present invention is decouple the cooling system and to provide a separate cooling gas driver remote from a cooling apparatus that is coupled to the heat-generating device. Furthermore, the cooling gas driver may be implemented either as a centralized unit disposed upstream or downstream of the cooling apparatus, or as a decentralized facility disposed both upstream and downstream thereof.

It is thereby possible to implement an efficient cooling gas driver that needs not to be incorporated in the interior of a small electronic or other cabinet, while coupling thereto a small cooling apparatus that is intimately associated with the heat generating device inside the cabinet. There is formed thereby an integral cooling system with a cooling gas driver and a cooling apparatus, both optimized and matched for providing enhanced cooling performance in operative association with the heat generating device.

### BRIEF DESCRIPTION OF THE DRAWINGS

In the drawings, like reference characters generally refer to the same parts throughout the different views. Also, the drawings are not necessarily to scale, emphasis instead generally being placed upon illustrating the principles of the invention. In the following description, various embodiments of the present invention are described with reference to the following drawings, in which:

FIGS. 1A to 1D are schematic block diagrams illustrating examples of the structure of the integral cooling system,

FIG. 2 shows an example of one embodiment of a cooling apparatus,

FIGS. 3A and 3B present two examples of a second embodiment of a cooling apparatus,

FIG. 3C is a representation of a three-dimensional porous conductor structure,

FIGS. 4 to 8 depict schematic diagrams of five exemplary embodiments of the integral cooling system, and

FIGS. 9A to 9C show a flowchart of a calculation procedure.

### DETAILED DESCRIPTION OF THE DRAWINGS

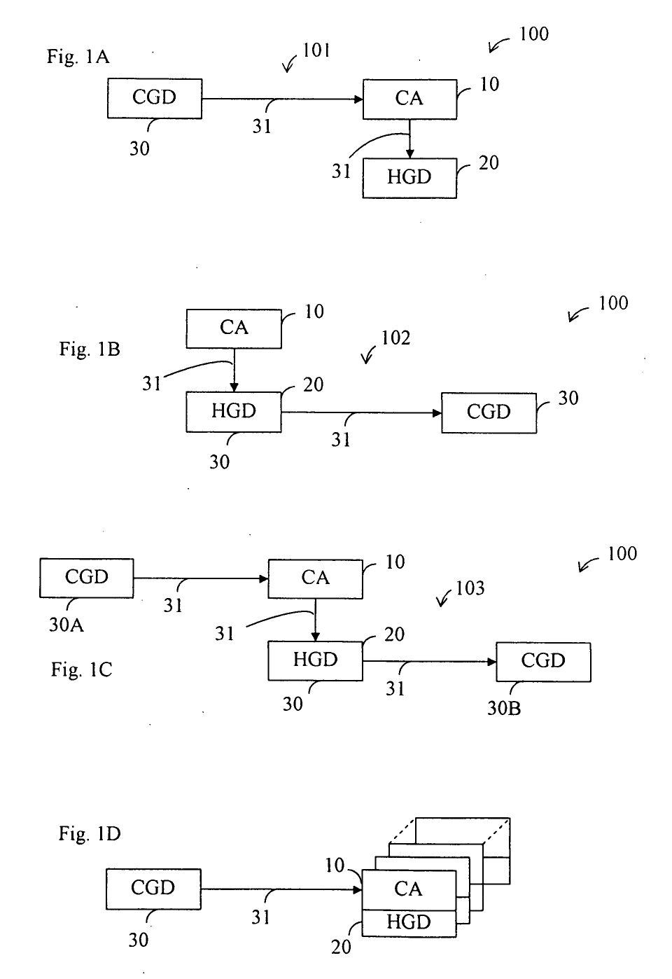

FIGS. 1A, 1B, 1C and 1D are schematic block diagrams showing examples of the structure of the integral cooling system 100 having as main elements a cooling apparatus 10 for cooling a heat generating device 20, and a cooling gas driver 30 configured to provide a flow of treated cooling gas 31 at a high-pressure differential through the cooling apparatus 10.

FIGS. 1A and 1B show a cooling gas driver 30 implemented as a centralized gas treatment facility, which is coupled upstream in FIG. 1A and downstream in FIG. 1B as a structure embodiment, respectively 101 and 102, operative with the cooling apparatus 10.

FIG. 1C presents a structure embodiment 103 of the cooling gas driver 30 as a distributed gas treatment facility having a first portion of the cooling gas driver 30A coupled upstream and a second portion of the cooling gas driver 30B coupled downstream of the cooling apparatus 10.

The cooling gas 31 is shown to flow downstream by the arrow indicated as 31 as driven by the absolute cooling gas pressure which is always higher upstream.

Treated coolant gas 31 generated by the cooling gas driver 30 thus flows through the cooling apparatus 10 where it may expand, and cools down the heat-generating device 20. Possibly, the heat-generating device 20 is any device, such as for example a CPU or other mechanical, or electric, or electronic component, which may or may not be mounted on a printed circuit board or any other substrate, and requires cooling. The integral cooling system 100 is not limited to a specific heat generating device of specific size or of given heat output but accommodates the heat-generating device to be cooled.

The cooling apparatus 10 is intimately coupled to the heat-generating device 20 but the cooling gas driver 30 may remain in fluid communication remote and away from the cooling apparatus 10 and from the heat-generating device 20. Such fluid communication is provided for example by pipes or tubing, either rigid or flexible that may be reversibly detachable when desired. It is thereby possible to dispose the cooling gas driver 30 away from the cooling apparatus 10 as is most practical for the needs and requirements at hand.

Although not shown in FIG. 1C, the distributed cooling gas driver unit 30A and the cooling gas driver unit 30B may have a single common shaft coupling between the different cooling gas driver units. For example, a compressor 30A and a turbine 30B may operate on a common shaft while both the compressor and the turbine are coupled to the cooling apparatus 10 and to the heat-generating device 20 by appropriate tubing. In other words, a same single shaft may couple different cooling gas driver units pertaining to a distributed cooling gas driver 30. The same is true for the configuration illustrated in FIG. 7 hereinbelow.

Furthermore, although not shown in the FIGS. 1A, 1B and 1D, the cooling gas driver 30, which is configured to deliver treated cooling gas 31 at a high pressure differential, has at least one element but may also include a plurality of devices, even when configured as a centralized facility.

FIG. 1D illustrates a structure embodiment 104, similar to the structure embodiment 101 of FIG. 1A, where one cooling gas driver 30 provides cooling gas 31 to more than one cooling apparatus 10 in parallel, as a single example of the many possible implementation configurations of the integral cooling system 100.

The integral cooling system 100 is thus able to deserve a plurality of cooling apparatus 10 and of heat generating device 20 simultaneously.

The cooling gas driver 30 may be selected from existing equipment to best suit the requirement of the cooling apparatus 10 operative in association with the heat-generating device 20 to achieve desired and controlled heat removal at minimum energy consumption. For example, the cooling gas driver 30 may include, alone and in combination, equipment such as an air compressor, a fan, a turbine unit, or any other type of turbo-machinery unit or component, a gas or liquid cooled heat exchanger, electric driving motors, an air conditioner, a refrigerator, as well as other known equipment for treating coolant gas. Hence, the cooling gas driver 30 may include compressing units for compressing gas, aspiration units for drawing gas in, and ancillary units for cooling, conditioning and refrigerating the cooling gas 31. In other words, the cooling gas driver is selected alone and in combination from the group of cooling gas driver 30 units consisting of compressing units, aspiration units, discharge turbines units, heat exchangers units, and ancillary units.

Preferably, but without being limited thereto, the coolant gas is air, such as available ambient air.

In general, the cooling gas driver 30 is selected from the group consisting of facilities being centralized upstream, centralized downstream, and distributed upstream and downstream.

The cooling gas driver 30 delivers a flow of coolant gas 31, providing treatment of cooling gas parameters such as for example gas pressure, gas temperature, gas humidity, gas flow speed and volume that is exploited by the cooling apparatus 10 to cool the heat generating device 20. Hence, the cooling gas driver 30 is different from a cooling fan as described in the prior art cited hereinabove. It is emphasized that the cooling gas driver 30 is an integral portion of the integral cooling system 100, and is customized and configured to integrally match and fit for operative association in combination with the cooling apparatus 10, with the purpose of effectively and energy efficiently cooling the heat-generating device 20 to desired controlled temperature levels, using minimum energy consumption.

Cooling gas drivers 30 are well known to those skilled in the art and therefore need not to be described in detail. However, the cooling gas driver 30 being one integral portion of the integral cooling system 100, it must be customized and configured to integrally match and fit for operative association in combination with the cooling apparatus 10, with the purpose of effectively and energy efficiently cooling the heat-generating device 20 to the desired controlled temperature levels.

Should the cooling gas driver 30 and/or the cooling apparatus 10 generate excessive or undesired acoustic emissions, then it is possible to use appropriate noise abatement techniques, such as a passive, system, or an active system, or both systems together, to provide desired sound suppression.

The integral cooling system 100 thus includes a cooling apparatus 10 as a first main component and a cooling gas driver 30 as a second main component both integrated and matchingly configured to effectively cool one or more heat generating devices 20 to required temperature levels.

The cooling apparatus 10 is configured as a chamber that is fixedly and intimately coupled to the heat-generating device 20. Preferably, the cooling apparatus 10 is adapted to fit the shape of the heat-generating device 20 to be cooled and presents at least one cooling gas inlet and at least one cooling gas outlet. The cooling gas outlet is designed to permit to exhaust the heated cooling gas directly to the ambient atmosphere or via reversibly detachable rigid or flexible tubing or piping to a convenient remote location.

Two main physical principles are being exploited for the operation of the cooling apparatus 10.

First comes the principle of chill production, based on gaseous cooling through an expansion process. During the cooling gas expansion process, achieved for example within a rotating turbine and/or through an array of static selected orifices, the pressure and the temperature of the cooling gas are reduced. Consequently, the cooled cooling gas is discharged at a colder temperature and used to cool the heat-generating device 20. For example, the array of orifices is implemented as an array of selected and computer-calculated nozzles having a predetermined distribution, specific shape and contour to provide efficient expansion of the cooling gas to emerge as jets of cooling gas out of the nozzles. These jets of cooling gas are directed to impinge upon a hot surface of the heat-generating device 20 and thereby absorb and extract heat therefrom. The heated air is thereafter exhausted in situ or to a remote location via reversibly detachable rigid or flexible duct(s) such as tube(s) or pipe(s).

Second, follows the principle of application of effective heat transfer techniques operative between the cold cooling gas, preferably air, and a hot surface of the heat-generating device 20. For example, a permeable partition implemented as a superior thermally conductive mass of porous material having interconnected orifices is intimately coupled to the heat-generating device 20 to absorb heat therefrom by conduction, which heat is simultaneously transferred away from the porous substance by the cooling gas 31. The heated air is thereafter exhausted in situ or to a remote location via reversibly detachable rigid or flexible duct(s) such as tube(s) or pipe(s).

The cooling apparatus 10 integrated within a cooling system 100 is selected as operating either jets of cooling gas or a conductive porous partition. However, notwithstanding the chosen mode of operation of the stand-alone cooling apparatus 10, this last one must be matched to fit for efficient operation with the independent cooling gas driver 30 coupled thereto to achieve the desired heat removal away from the heat-generating device 20. Thus although both the cooling apparatus 10 and the cooling gas driver 30 function separately and away from each other, they are complementary matching units that must be functionally integrated by the application of design and calculation methods including for example, gas dynamics aerodynamics, and heat transfer, all well known to the art. These design and calculation methods take the cooling requirements of the heat-generating device 20 into account to match thereto the various design parameters necessary for the implementation of both the cooling gas driver 30 and the cooling apparatus 10. In other words, the integral cooling system 100 is designed and calculated to minimize overall energy consumption, minimize its global dimensions, and maximize the cooling performance of the system with respect to given heat-generating device(s) 20.

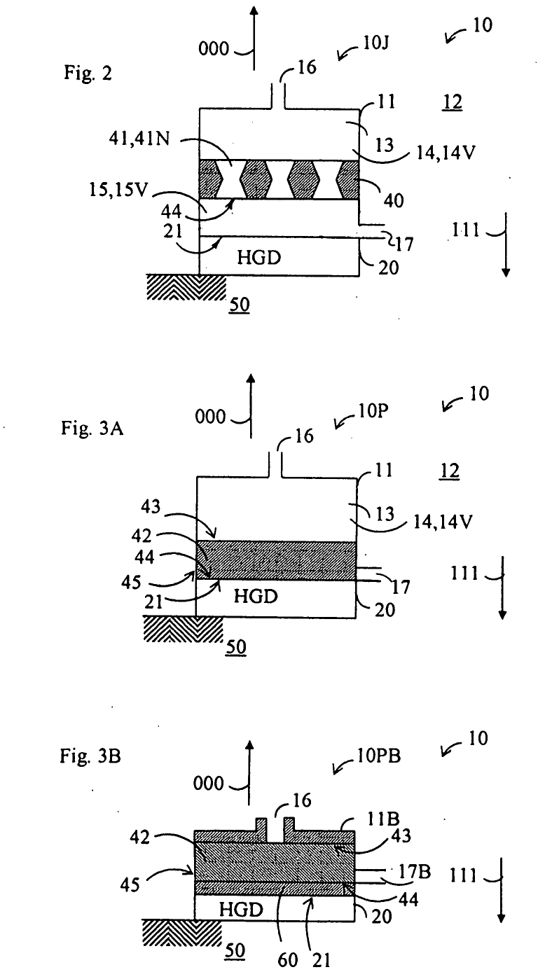

FIG. 2 shows an example of an embodiment 10J of a cooling apparatus 10 operating jets of cooling gas, with the arrows 000 and 111 generally designating, respectively, the upstream, and the downstream direction. The cooling apparatus 10 has a closed housing 11 with a housing exterior 12 and a housing interior 13 having an upstream cooling chamber 14 with a cooling volume 14V, which is closed downstream by a permeable partition 40 perforated by orifices 41. The orifices 41 allow passage of cooling gas 31, not shown in FIG. 2, through the partition 40 from the cooling chamber 14 to the expansion chamber 15. Downstream of the partition 40, there is disposed an expansion chamber 15, having an expansion volume 15V. The most downstream portion of the cooling apparatus 10 is fixedly coupled to the heat-generating device 20. Cooling gas 31 penetrates into the cooling apparatus 10 via at least one cooling gas inlet 16 entered and supported by the housing 11, and exits thereout through at least one cooling gas outlet 17.

A key feature of the orifices 41 is that they may be configured as nozzles 41N having a computer designed and calculated size and shape. The shape of the nozzle(s) is designed to minimize losses and to ensure maximum expansion and optimal jet velocities. The internal contour of the nozzles 41N has a curved upstream inlet surface with small radii and is followed by a downstream nozzle diameter varying along the centerline of the nozzle. The internal surface of the nozzle 41N is kept smooth to minimize nozzle-wall friction losses. The orifices 41 and the nozzles 41N may be distributed over the partition 40 as desired, either uniformly, or in an organized distribution, or randomly, to optimize heat transfer and minimize energy consumption.

In other words, the fluid permeable partition 40 has a plurality of orifices, where each orifice out of the plurality of orifices is shaped as an optimal aerodynamic nozzle 41N allowing the cooling gas to expand therethrough. An expansion chamber 15 is disposed downstream of the permeable partition 40, which has a downstream surface that is separated at a predetermined distance away from the upstream surface 21 of the heat-generating device, for the cooling gas to exit and expand downstream of the nozzles as jets of cooling gas directed to impinge upon and collect heat to cool the heat-generating device. Furthermore, the expanded cooling gas outlet entered in the expansion chamber has a predetermined size wherethrough the heated cooling gas controllably transfers heat away from the heat-generating device out of the cooling apparatus after having absorbed heat therefrom.

In the various embodiments of the cooling apparatus 10 described hereinbelow, it is assumed that the cooling apparatus 10 is fixedly attached directly or indirectly to the heat generating device 20, which is itself fixedly retained to a substrate 50 such as a printed circuit board for example. However, if desired, the cooling apparatus 10 and the heat-generating device 20 may each be fixed separately to the substrate 50 while remaining intimately coupled together.

When high differential pressure is applied between the upstream and downstream sides of the nozzle partition 41N, with pressure values sufficient to create supersonic flow through the nozzles 41N, each nozzle may also include an internal narrower cross section, thus a throat, followed downstream by a nozzle portion with a small divergent angle according to classical aerodynamic design rules of supersonic nozzles. The exact contour of the nozzles 41N is determined by specific dedicated computerized calculations, as is well known to the art.

In operation, cooling gas 31 enters the cooling chamber 14 of the cooling apparatus 10 through a single cooling gas inlet 16, or if desired and although not shown in FIG. 2, through a plurality of cooling gas inlets 16. The cooling chamber 14 is configured to feature a relative large volume 14V, relative to the volume 15V of the expansion chamber, for the cooling gas 31 to be uniformly distributed therein while ensuring minimum air turbulence and minimum stagnation pressure losses.

The expansion process of the cooling gas 31 is achieved through the nozzles 41N and is caused by the pressure difference existing between the inlet chamber 14 with the higher pressure, and the expansion chamber 15 with the lower pressure. The absolute pressure in the inlet chamber 14 may vary and be either higher or lower than that of the surrounding atmospheric pressure, in accordance with the mode of operation, the configuration, and the operating conditions of the integral cooling system 100. In all the described embodiments the absolute upstream pressure in the cooling apparatus 10 is always higher than that of the downstream pressure, and always higher in the inlet chamber 14 than in the expansion chamber 15.

Downstream of the partition 40, the cooling gas 31 exits into the expansion chamber 15 as jets of cooling gas that impinge directly on the upstream surface 21 of the heat generating device 20 to extract and absorb heat therefrom. Thereafter, the expanded cooling gas 31 leaves the closed expansion chamber 15 through the cooling gas outlet 17. Although not shown in FIG. 2, more than one cooling gas outlet 17 may be provided if desired. The single or many cooling gas outlets in all the described configurations may have a predetermined size for the purpose of controlling gas outlet capacity.

The effective operation of the integral cooling system 100 is achieved by the careful mutual matching of cooling gas flow and cooling apparatus 10 parameters in response to the required cooling of the heat-generating device 20. Some important cooling apparatus 10 parameters are for example the volume of the cooling and expansion chambers, respectively 14V and 15V, the distribution and configuration of the orifices 41 in the partition 40, the shape of the downstream face 44 of the partition 40, the distance of the downstream face 44 from the heat generating device, and the number and size of the cooling gas inlets and outlets, respectively 16 and 17. It is noted that the downstream face 44 of the partition 40 as well as the upstream surface 21 of the heat-generating device 20 are not necessarily plane surfaces. For the sake of enhanced heat transfer, one of or both of the downstream face 44 and the upstream surface 21 may have fins, ribs, grooves, or any other non-planar surface configuration.

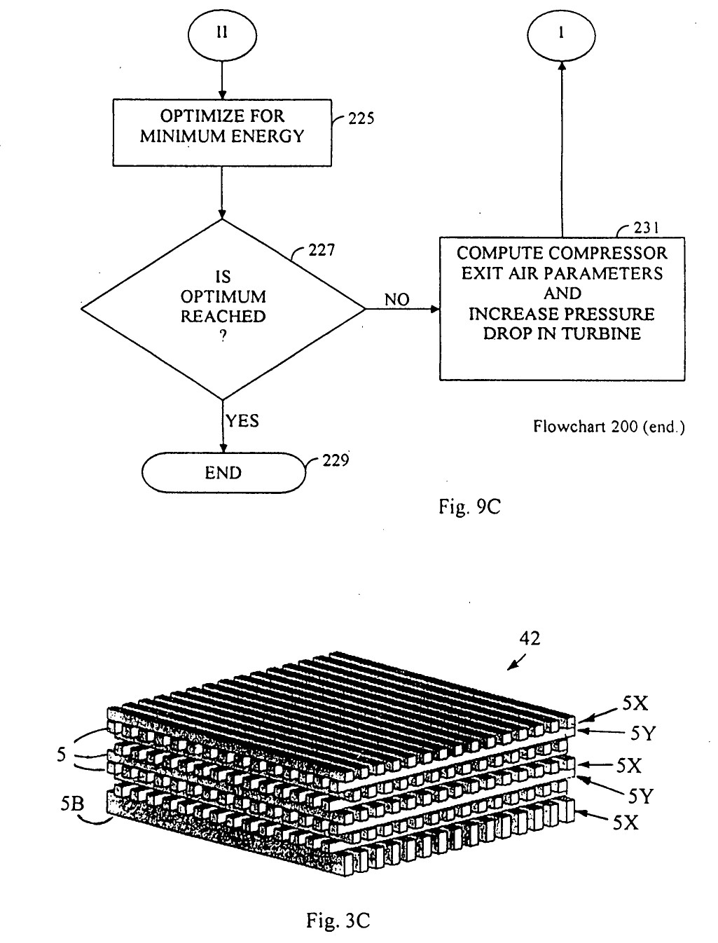

FIG. 3A shows an example of an embodiment 10P of a cooling apparatus 10 operative with a conductive porous partition, with the arrows 000 and 111 generally designating, respectively, the upstream, and the downstream direction. The embodiment 10P is similar to the embodiment 10J shown in FIG. 2 but for a different partition 40 and the absence of the expansion chamber 15, the volume of which may be considered to have been collapsed to nil.

Reference to the coupling of the cooling apparatus 10, the heat-generating device 20, and the substrate 50 has been made hereinabove and is not repeated.

The embodiment 10P of the cooling apparatus 10 has a closed housing 11 with a housing exterior 12 and a housing interior 13 having an upstream cooling chamber 14 with a cooling volume 14V, which is closed downstream by a fluid permeable partition 42 having interconnected orifices. The permeable partition is configured as a porous thermal conductor 42 having orifices such as interconnecting pores to allow flow of the cooling gas 31 from upstream to downstream through the partition 42. The cooling gas 31 is not shown in FIG. 3A.

The upstream upper face 43 of the partition 42 closes the cooling chamber 14 while the downstream face 44 of the partition 42 is in close contact with and abuts the upstream surface 21 of the heat-generating device 20. The porous thermal conductor 42 is thus intimately and properly disposed to absorb the heat generated by the heat-generating device 20.

In operation, the cooling gas 31 that entered the cooling apparatus 10 via the cooling gas inlet 16 penetrates the porous thermal conductor 42 to first absorbs heat therefrom and to then exits via the cooling gas outlet 17 entered in the housing 11 of the cooling apparatus 10. Although not shown in FIG. 3A, more than one cooling gas outlet 17 may be provided if desired, for control of the cooling gas exit.

In other words, the permeable partition 42 has a plurality of orifices forming interconnecting pores, and is implemented as a porous thermal conductor 42 having an upstream face 43 closing the cooling chamber, a downstream face 44 abutting the heat-generating device, and sidewalls 45 connecting the upstream face to the downstream face. Furthermore, the cooling gas 31 expands via the pores to absorb heat collected by the thermal conductor 42 from the heat generating device 20, and exits via the sidewalls 45 to transfers heat out of the cooling apparatus and out of and away from the heat-generating device FIG. 3B depicts an example of another embodiment 10PB of the cooling apparatus 10 having a conductive porous partition 42, but slightly different from the embodiment 10P shown in FIG. 3A. The housing 11B is now open and accommodated to cover the upstream upper face 43 and only a portion of the surface of the sidewalls 45 of the partition 40, thus leaving free and uncovered a large portion of the surface of the sidewalls 45. The cooling gas inlets 16 is still entered into and supported by the housing 11B but the cooling chamber 14 is absent, the volume of which may be considered to have been collapsed to nil. Nevertheless, although not shown in FIG. 3B, the embodiment 10PB may also include a cooling chamber 14 having a volume 14V.

The downstream face 44 of the partition 42 may be disposed in enhanced close contact with the upstream surface 21 of the heat-generating device 20 by the addition of an intermediate layer 60 of conductive adhesive material if desired. It is also possible to enhance the upstream surface 21 of the heat-generating device 20 by adding thereto a heat sink, such as a thermally conductive plate for example, that has a larger surface than the upstream surface 21. The upstream surface of the thermally conductive plate may not necessarily have a flat planar surface.

Furthermore, should the free uncovered portion of the surface of the sidewalls 45 of the partition 42 present too large an outlet surface for the cooling gas then the partition 40 may be encapsulated. Encapsulation means covering the surface of the sidewall 45, or all or any desired surface of the partition 42 with a gas-tight material, and opening in the encapsulation material one or more cooling gas outlets of a size as large as desired for control purposes, as schematically indicated by the arrow 17B in FIG. 3B.

In operation with a conductive porous partition 42, the cooling gas 31 enters the cooling apparatus 10 via the cooling gas inlets 16 and the cooling chamber 14 if existent. The cooling gas 31 is not shown in FIG. 3B. The heat that is being conducted from the heat-generating device 20 into the porous thermal conductor material 42 is transferred by convection into the cooling gas 31 that travels within the intercommunicating cavities coupling the pores of the porous conductor 42. The superior heat conductivity and the very large surface area of the porous conductor 42 are critical characteristics for the operation of the cooling apparatus 10. To optimize the airflow within the porous conductor 42, it is important to include the three-dimensional distribution of the porous substance void fraction as a design parameter. The cooling gas 31 thus absorbs the heat previously collected by the partition 42 from the heat-generating device 20, and exits out of the partition 42 via the cooling gas outlet(s) 17 or through the single or many gas outlets 17B opened in the encapsulation material.

Furthermore, the porous conductor 42 does not necessarily present randomly configured pores, but may be built as a carefully designed three-dimensional geometric structure. Such a porous conductor structure 42 may have exactly predetermined interstices with a large active area for contact with the cooling gas, where the structure is configured as a selected sculptured mass of conducting material. For example, such a porous structure 42 may have layers of parallel rods separated away from each other by a determined distance, each layer in perpendicular to the adjacent layer, whereby a porous three-dimensional lattice is erected. The rods, which need not to be identical, may be of any desired cross-section, such a circle for a slender cylinder and a square for a parallelepiped. Thereby, a structure with a selected porosity is achieved, which may be configured according to desired fluid mechanics and heat transfer properties, in compatibility with computation programs.

FIG. 3C shows an example of a designed conducting porous structure 42 having selected properties and parameters, suitable for input into fluid flow calculations. The structure 42 is configured as a stack of successive parallel arrays of rods, with one planar array 5X of parallel and mutually distanced away rods 5 perpendicular to another planar array 5Y of parallel and mutually distanced away rods 5. As shown in FIG. 3C, the cross-section of the rods may differ, for example, by rods 5B being different from rods 5.

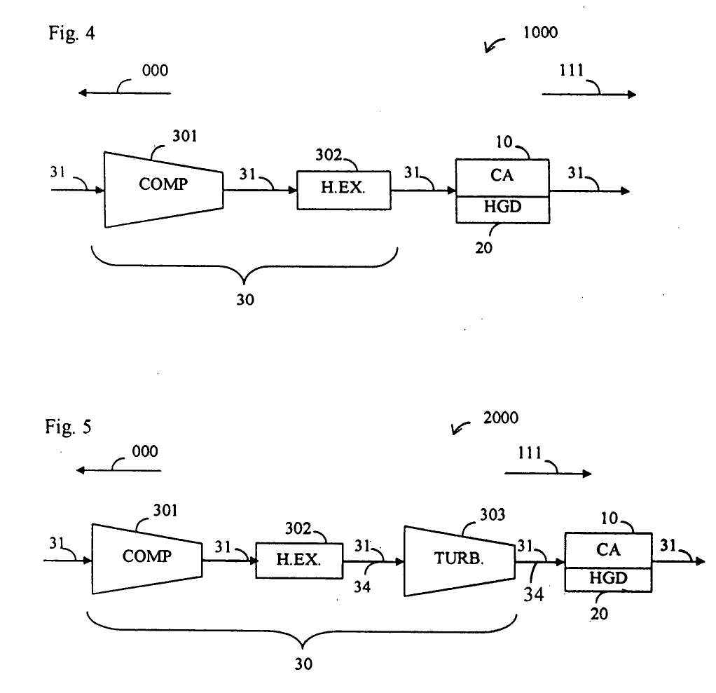

FIGS. 4 to 7 present examples of possible practical embodiments of the integral cooling system 100.

FIG. 4 is a schematic diagram of a first embodiment 1000 as a first example of the implementation of the integral cooling system 100 using air as the cooling gas 31. In the embodiment 1000 the cooling gas driver 30 disposed upstream is selected as a centralized unit having a compressor 301 and a heat exchanger 302 coupled to the cooling apparatus 10, which is itself coupled to the heat-generating device 20.

The ancillary equipment needed to power and properly operate the cooling gas driver 30 are implicitly included and neither mentioned separately hereinbelow nor shown in the Figs. since it is well known to anyone with ordinary skill in the art. For example the compressor 301 is possibly powered by an electric motor and the heat exchanger 302, operating with air, or when operating with a liquid coolant, may perhaps need further equipment such as a cooling fluid, a fluid reservoir, and a pump.

In FIG. 4 air, indicated by the arrow 31, is compressed by the compressor 301, then cooled through the heat exchanger 302 with minimal pressure drop, and next delivered to the cooling apparatus 10 as pressurized air at ambient temperature. The pressurized air 31 delivered by the cooling gas driver 30 is pushed into the cooling apparatus 10 where it undergoes an expansion process until an air pressure value is reached that is slightly higher than the ambient atmospheric pressure while simultaneously reducing the temperature of the air 31 to low values.

When the nozzle-type cooling apparatus 10 operating jets of cooling gas 31 as shown in FIG. 2 is implemented with the embodiment 1000, the air 31 is accelerated to expand and form high-speed jets of cold air that impinge upon the heat generating device 20 to absorb heat therefrom, and to then exit the cooling apparatus 10.

When the porous thermal conductor 42 shown in FIGS. 3A and 3B is implemented with the embodiment 1000, the compressed air 31 flows through the communicating cavities of the pores thereof. Thereby, the compressed air 31 absorbs heat transferred by the heat-generating device 20 to the thermal conductor 42 before exiting to the environment, or being ducted away as described hereinabove.

FIG. 5 is a schematic diagram of a second embodiment 2000 as a second example of the implementation of the integral cooling system 100 using air as the cooling gas 31. In the embodiment 2000 the cooling gas driver 30 is again selected as a centralized unit disposed upstream and having a compressor 301 and a heat exchanger 302 as with the embodiment 1000, but the cooling gas driver 30 is enhanced by the addition of an exhaust turbine 303 which is coupled to the cooling apparatus 10, in turn coupled itself to the heat-generating device 20.

As with the embodiment 1000, the compressor 301 supplies compressed air, shown as arrow 31, which is cooled through the heat exchanger 302 to ambient temperature. Next, the compressed air 31 undergoes an expansion process through the dedicated turbine 303. The pressure of the compressed air 31 is reduced to an intermediate pressure ranging between the discharge pressure of the compressor 301 and the ambient pressure and thereby, reduces the temperature of the compressed air 31 to values below the ambient temperature.

The enhanced cooling gas driver 30 displays relatively more absolute cooling capacity and is better suited for conditions where humid air may prevail and condensation may occur. Hence, condensed water vapor from the humid air may be collected from the compressed air 31 at the heat exchanger 302, thereafter becomes cold and dry air. The cold, dry, and pressurized air 34 is delivered by the turbine 303 and pushed into the cooling apparatus 10 to undergo therein a second expansion until ambient atmospheric pressure, thereby reducing the temperature of the air 34 to even lower values.

When the nozzle-type cooling apparatus 10 operating jets of cooling gas 31 as shown in FIG. 2 is implemented with the embodiment 2000, the air 34 is accelerated to expand and form high-speed jets of cold air that impinge upon the heat generating device 20 to absorb heat therefrom, and to then exit the cooling apparatus 10.

When the porous thermal conductor 42 shown in FIGS. 3A and 3B is implemented with the embodiment 2000, the cold, dry and pressurized air 34 flows through the interconnected cavities of the pores thereof. Thereby, the pressurized air 34 absorbs heat transferred by the heat-generating device 20 to the thermal conductor 42 before exiting to the environment, or being ducted away as described hereinabove.

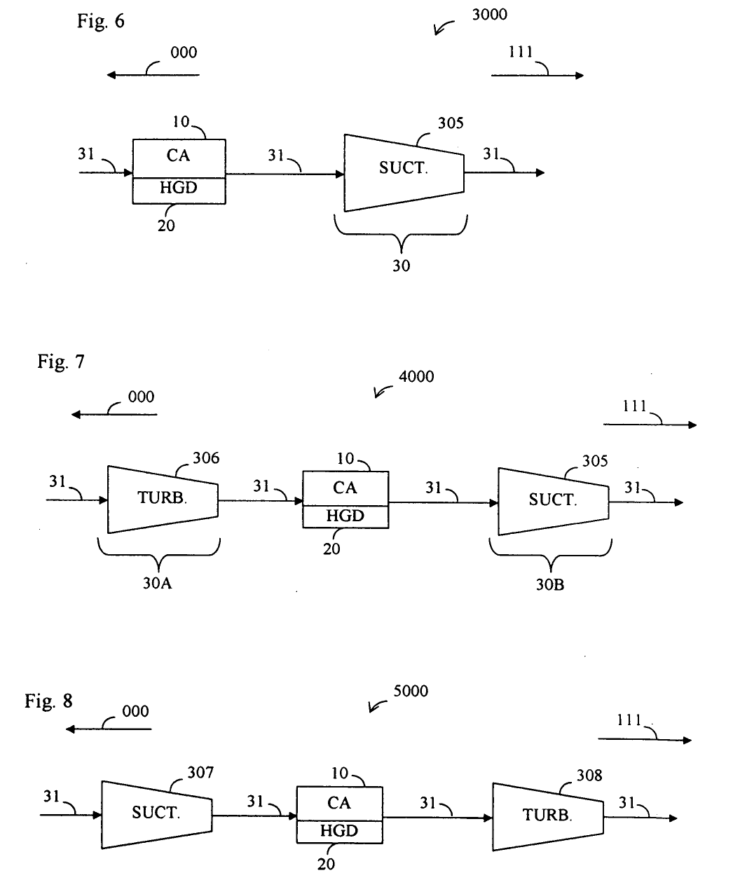

FIG. 6 is a schematic diagram of a third embodiment 3000 as a third example of the implementation of the integral cooling system 100, using air as the cooling gas 31.

In the embodiment 3000 the cooling gas driver 30 is still a centralized unit, but here use is made of a downstream disposed suction unit 305, such as a vacuum pump or a compressor operating in suction mode, which is coupled to the cooling apparatus 10 disposed upstream, which is itself coupled to the heat-generating device 20.

The suction pump 305 coupled downstream of the cooling apparatus 10 creates a sub-atmospheric pressure therein. Thereby, ambient air 31 is sucked from the surroundings to enter into the cooling apparatus 10 to cool the heat-generating device 20.

When the nozzle-type cooling apparatus 10 operating jets of cooling gas 31 as shown in FIG. 2 is implemented with the embodiment 3000, the air 31 is sucked-in and accelerated to expand and form high-speed jets of cold air that impinge upon the heat generating device 20 to absorb heat therefrom, and to then exit the cooling apparatus 10.

When the porous thermal conductor 42 shown in FIGS. 3A and 3B is implemented with the embodiment 3000, the sucked-in air 31 flows through the cavities of the pores thereof. Thereby, the air 31 absorbs heat transferred by the heat-generating device 20 to the thermal conductor 42 before exiting to the environment, or being ducted away as described hereinabove.

FIG. 7 is a schematic diagram of a fourth embodiment 4000 as a fourth example of the implementation of the integral cooling system 100 using air as the cooling gas 31. In the embodiment 4000 the cooling gas driver 30 is a distributed unit having an expansion turbine 306 upstream, designated as 30A, and downstream thereof, a suction unit 305 indicated as 30B, such as a vacuum pump or a compressor operating in reverse mode. In the embodiment 4000 the following elements are coupled in succession from upstream to downstream: first the expansion turbine 306, second the cooling apparatus 10 coupled to the heat generating device 20, and third and last, the suction unit 305.

The suction unit 305 creates a sub-atmospheric pressure in the cooling apparatus 10, which sucks-in ambient air into the expansion turbine 306. The air 31 that is sucked-in at ambient atmospheric air pressure thus passes first through the expansion turbine 306 to become expanded to an intermediate sub-atmospheric pressure and cooled, as a first expansion stage. Thereafter, the cold air 31 undergoes a second expansion stage in the cooling apparatus 10, passing from the intermediate sub-atmospheric pressure to a lower sub-atmospheric pressure before entering the suction unit 305.

When the nozzle-type cooling apparatus 10 operating jets of cooling gas 31 as shown in FIG. 2 is implemented with the embodiment 4000, the air 31 undergoes an expansion process from an intermediate sub-atmospheric pressure in the cooling chamber 14 to a lower sub-atmospheric pressure in the expansion chamber 15, while the temperature of the air 31 is simultaneously reduced. The expansion process results in the creation of high-speed jets of cold air that impinge directly upon the heat-generating device 20 and absorb heat therefrom, whereby the temperature of the heat-generating device 20 is lowered.

When the porous thermal conductor 42 shown in FIGS. 3A and 3B is implemented with the embodiment 4000, incoming ambient air flows through the communicating internal cavities of the porous substance thermal conductor 42, since the flow of cooling air 31 is driven by the pressure difference created by the downstream suction unit 305 and affected by the expansion turbine 306 upstream thereof. Thereby, the air 31 absorbs heat transferred by the heat-generating device 20 to the thermal conductor 42 before exiting to the environment, or being ducted away as described hereinabove.

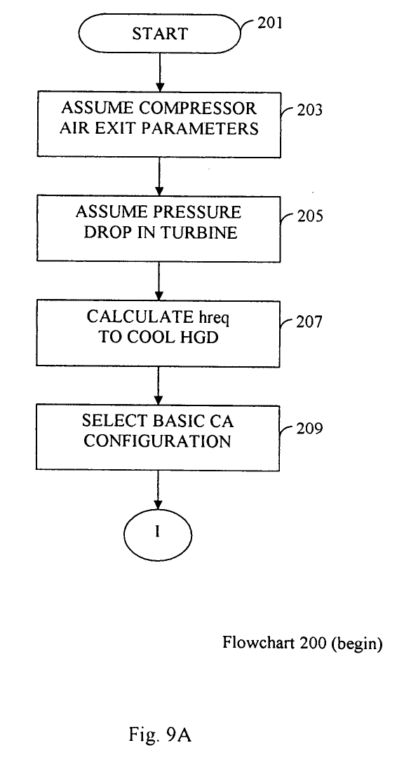

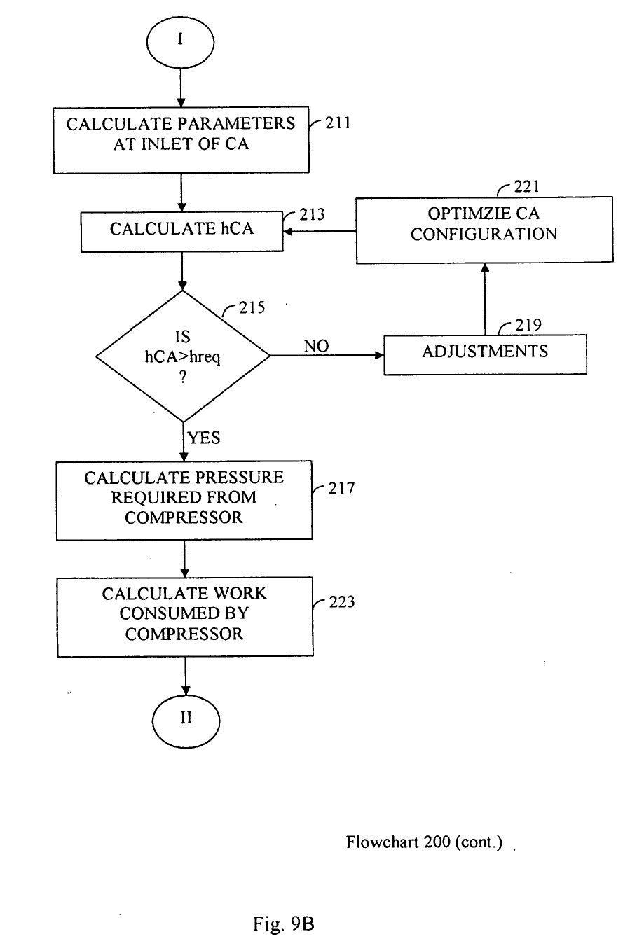

FIG. 8 showing a fifth embodiment 5000 of the implementation of the integral cooling system 100 using air as the cooling gas 31, and the flowchart 200, depicted as FIGS. 9A, 9B and 9C, are now referred to.

FIG. 8 depicts a distributed cooling gas driver 30 implemented as a compressor 307 coupled to and upstream of a cooling apparatus 10 associated with a heat generating device 20, and a turbine 308 coupled thereto and downstream thereof.

A simplified example of the considerations to be taken in account for the implementation of the integral cooling system 100 is provided hereinbelow. It is emphasized that the cooling gas driver 30 and the cooling apparatus 10 cannot be calculated and optimized separately but must be customized and configured to integrally match and fit together for operative association in combination, for the purpose of effectively and energy efficiently cooling the heat-generating device 20 to the desired temperature levels.

The following acronyms are used for the sake of conciseness:

| | |
|---|---|
| Integral cooling system: | ICS |
| Cooling gas driver: | CGD |
| Cooling apparatus: | CA |
| Heat generating device: | HGD |

The conditions for the calculation or computation of the energy consumption of integral cooling system 100 are described hereinbelow as an example only. It is assumed that the cooling gas 31 is air.

a. The heat flux generated by a HGD is assumed as, without being limited thereto, uniformly distributed along a surface and its maximum value is pre-determined, for example, it may equal to 100 W. The maximum surface temperature of the heat generating device is specified by its manufacturer, for example it may be limited to 60.0° C. The temperature of the cooling air incoming via the cooling gas inlet 16, as shown in FIGS. 2, 3A, and 3B, is determined by the specific operational conditions of the case at hand, for example it may equal to 40° C. Hence the temperature of the incoming air at the inlet 16 is set as Tdes=313° K.
b. The surface of the area of the HGD to be cooled is typically presented as a rectangular or a square plate with predetermined dimensions, for example 30×30 mm. If desired, the surface of the HGD may be enhanced, for example by coupling thereto a thermal conductive plate of size larger than the surface of the HGD, forming a heat sink.
c. Other assumptions and limitations may include:
A maximum air velocity that may be limited to, for example, V<250 m/s.
A maximum air inlet total stagnation temperature, downstream of the compressor 307 not exceeding the ambient temperature by more than 5° C. for example.
The maximum total heat exchanger pressure losses are designed to be less than 5% of the incoming air pressure at the inlet 16.
   d. Conditions for the CA when selected as embodiment 10J having a permeable partition 40 perforated by orifices 41, may include for example:
A maximum orifice distribution density of X/D and Y/D≧1.5, where
   D is the nominal diameter of an orifice 41
   X is the longitudinal distance between orifices
   Y is the lateral distance between orifices, with Y perpendicular to X.
A maximum local distance Z separating between the downstream surface portion of the permeable partition 40 and the upstream surface portion of the HGD being limited to Z/D<15. Z is perpendicular to the X-Y plane.
A minimum nominal orifice diameter D set as, for example, D>50 μm.
D, X, Y, and Z are not shown in the Figs.
   e. The adiabatic efficiency of the various components, such as the compressor and the turbine for example is as a first approximation, assumed to have a fixed value, for example ηcomp=0.7 and ηturb=0.75 for the efficiency of, respectively, the compressor 307 and the turbine 308. The detailed calculations link the parameters and performance of the compressor 307 and the turbine 308 to their respective operating condition.

In FIGS. 9A to 9C, the flowchart 200 is an example of some of the highlights of the procedure used to calculate an integral cooling system 100, making reference to only some of the parameters involved in the procedure. Unless otherwise specified, the procedure continues sequentially from one step to the other.

The flowchart 200 presents an example of the calculations required to materialize a system and a method for implementing a cooling apparatus 10 having an upstream direction 000 and a downstream direction 111, the cooling apparatus being coupled to and configured for cooling a heat-generating device 20 disposed downstream thereof by operatively coupling a cooling gas driver 30 to the cooling apparatus for driving a cooling gas 31 therein. The cooling apparatus 10 has a housing 11 with an interior 13 including an upstream cooling chamber 14 having a volume 14V which is closed downstream by a permeable partition 40, and has a cooling gas inlet 16 for receiving the cooling gas at a higher inlet pressure and for expanding the cooling gas downstream at a pressure lower than the higher inlet pressure. The system and the method are characterized by comprising the steps of:

configuring the cooling gas driver 30 as either one of both a centralized and a distributed gas driving facility dedicated to provide a flow of treated cooling gas 31 at a high-pressure differential through the cooling apparatus 10, the cooling gas driver being disposed remote and away from the cooling apparatus and from the heat generating device 20,

providing a plurality of orifices 41 within the permeable partition 40 or 42 to permit gas flow from upstream to downstream thereof,

selecting appropriately governing parameters for the cooling apparatus, for the partition and for the cooling gas driver, and calculating mutual operative matching to achieve optimal cooling in association with the heat generating device, and

providing an expanded cooling gas outlet 17, 17B for exit of the heated cooling gas 31 out of the cooling apparatus,

whereby the cooling gas is used to absorb heat from and transfer heat away from the heat-generating device.

FIG. 9A presents the preliminary steps of the flowchart starting with the first step 201, in relation with the embodiment 5000 shown in FIG. 8.

In steps 203 and 205 an assumption is made for the input value of, respectively, the air pressure at the exit downstream of the compressor 307 and the pressure drop in the turbine 308. Thereafter, in step 207, the heat transfer coefficient, referred to as hreq, required to cool the HGD is calculated. In step 209, a basic configuration is selected for the CA.

The preliminary steps terminate with the flowchart junction point encircling the roman digit I, from where the procedures continues to step 211, shown FIG. 9B.

In step 211 and 213 calculations are carried out for, respectively, the parameters of the cooling air entering the CA, and the heat transfer coefficient hCA of the CA. These calculations can be performed in different ways; analytically, using experimental correlations from the existing literature or by detailed computational fluid dynamics (CFD).

It is in step 215 that the comparison is made between the heat transfer coefficient hCA of step 213 and the heat transfer coefficient hreq of step 207. If the heat transfer coefficient hCA is greater than the heat transfer coefficient hreq, thus when positive, then the flow of the procedure continues to step 217, but else if negative, the flow passes to step 219.

In step 219 adjustments are made to parameters related to the CA and to the cooling gas driver CGD, in the aim of adjusting the system to reach a positive result for the condition imposed by step 215.

Regarding the CA, it is possible to enter small increment δ adjustments to at least one of the parameters Z/D, Y/D, X/D, and to the diameter D. For example, by increasing by a small increment 6 the ratio Z/D, and/or by decreasing by a small amount δ the ratio Y/D, X/D, and the diameter D.

Furthermore, it is also possible to increase the operating cooling air pressure delivered by the compressor 307.

In step 221, optimization is calculated for the configuration of the CA, whereafter the flow of the procedure returns for another loop through steps 213 and 215.

When the outcome of the comparison made in step 215 is positive, the procedure flows to step 217 where the cooling air pressure, to be delivered at the downstream exit of the compressor 307, is calculated. Next, in step 221, the work consumed by the compressor 307 is calculated.

The flowchart junction point encircling the roman digit II is the last step in FIG. 9B, from where the procedures continues to step 225, shown FIG. 9C.

In FIG. 9C, in step 225 the system is optimized for minimum energy consumption. Then, in step 227, a comparative check is made to find out if the energy consumption has reached an optimum. This comparison is made with results obtained from other calculation loops, not shown in the flowchart 200 for the sake of simplicity. Since the procedure described by help of the flowchart 200 is iterative, at least a few loops with different assumptions are calculated and compared.

Step 229 is the last step of the procedure in case when the outcome of step 227 is positive. In the contrary, for a negative result from step 227, the procedure continues to step 231 where the parameters of the cooling air exiting downstream of the compressor 307 and the air pressure drop in the turbine 308 are adjusted. The step 231 is actually an iterative search step striving to reach the best possible result for the cooling air exiting downstream of the compressor 307 and the air pressure drop in the turbine 308. Once a satisfactory results is obtained, the procedure loops back to the flowchart junction point roman I shown as the last step in FIG. 9A.

When the cooling apparatus 10 includes a thermally conductive mass of porous material 42, then the procedure described with reference to Flowchart 200 is slightly different. These differences regard mainly step 209, where a proper CA configuration is selected, steps 211 to 215, and steps 219 and 221. Evidently, the parameters adjusted in step 219 are different, and intensive use is made of computational fluid mechanics (CFD).

### INDUSTRIAL APPLICABILITY

The integral cooling system 100 is applicable in industry for cooling heat-generating devices operating for example, in conjunction with electric, electronic, computer, and mechanical components, and with communication equipment.

It will be appreciated by persons skilled in the art, that the present invention is not limited to what has been particularly shown and described hereinabove. Rather, the scope of the present invention is defined by the appended claims and includes both combinations and subcombinations of the various features described hereinabove as well as variations and modifications thereof which would occur to persons skilled in the art upon reading the foregoing description. For example, the cooling apparatus 10 is not limited to the embodiment 10J having an array nozzles 41N or to the embodiment 10P featuring a porous thermal conductor 42, but other embodiments are possible.

I claim:

1. A method for implementing a cooling apparatus having an upstream direction and a downstream direction, the cooling apparatus being coupled to and configured for cooling a heat-generating device disposed downstream thereof by operatively coupling a cooling gas driver to the cooling apparatus for driving a cooling gas therein,
the cooling apparatus having a housing with an interior including an upstream cooling chamber having a volume which is closed downstream by a permeable partition, and having a cooling gas inlet for receiving the cooling gas at a higher inlet pressure and for expanding the cooling gas downstream at a pressure lower than the higher inlet pressure,
wherein the method comprises the steps of:
configuring the cooling gas driver as either one of both a centralized and a distributed gas driving facility dedicated to provide a flow of treated cooling gas at a high-pressure differential through the cooling apparatus, the cooling gas driver being disposed remote and away from the cooling apparatus and from the heat generating device;
providing a plurality of orifices within the permeable partition to permit gas flow from upstream to downstream thereof;
selecting appropriately governing parameters for the cooling apparatus, for the partition and for the cooling gas driver, and calculating mutual operative matching to achieve optimal cooling in association with the heat generating device; and
providing an expanded cooling gas outlet for exit of the heated cooling gas out of the cooling apparatus,
whereby the cooling gas is used to absorb heat from and transfer heat away from the heat-generating device.

2. The method according to claim 1, wherein:
the permeable partition has a plurality of orifices, where each orifice from among the plurality of orifices is shaped as an optimal aerodynamic nozzle allowing the cooling gas to expand therethrough;
an expansion chamber is disposed downstream of the permeable partition, which has a downstream surface that is separated at a predetermined distance away from the upstream surface of the heat-generating device, for the cooling gas to exit and expand downstream of the nozzles as jets of cooling gas directed to impinge upon and collect heat to cool the heat-generating device; and
the expanded cooling gas outlet entered in the expansion chamber has a predetermined size wherethrough the heated cooling gas controllably transfers heat away from the heat-generating device out of the cooling apparatus after having absorbed heat therefrom.

3. The method according to claim 1, wherein:
the permeable partition is implemented as a porous thermal conductor having an upstream face closing the cooling chamber, a downstream face abutting the heat-generating device, and sidewalls connecting the upstream face to the downstream face; and
the cooling gas expands via the pores to absorb heat collected by the thermal conductor from the heat generating device, and exits via the sidewalls to transfers heat out of the cooling apparatus and out of and away from the heat-generating device and the upstream face of the HGD is configured as a non-planar surface.

4. The method according to claim 3, wherein the volume of the upstream cooling chamber is reduced to nil.

5. The method according to claim 1, wherein the cooling gas driver is selected from the group consisting of facilities being centralized upstream, centralized downstream, and distributed upstream and downstream.

6. The method according to claim 1, wherein the cooling gas driver is selected alone and in combination from the group of cooling gas driver units consisting of compressing units, aspiration units, discharge turbines units, heat exchangers units, air conditioner units, refrigerator units, and ancillary units.

7. The method according to claim 1, wherein a same single shaft couples different cooling gas driver units pertaining to a distributed cooling gas driver.

8. The method according to claim 1, wherein the cooling gas is selected as air.

9. The method according to claim 1, wherein the cooling gas driver is an integral portion of the integral cooling system, and is customized and configured to integrally match and fit for operative association in combination with the cooling apparatus, with the purpose of effectively and energy efficiently cooling the heat-generating device to desired controlled temperature levels, minimizing energy consumption.

10. The method according to claim 1, wherein the cooling gas driver comprises a system for active sound suppression.

11. An integral cooling system including a cooling apparatus having an upstream direction and a downstream direction, the cooling apparatus being coupled to and configured for cooling a heat-generating device disposed downstream thereof by operatively coupling a cooling gas driver to the cooling apparatus for driving a cooling gas therein,
the cooling apparatus having a housing with an interior including an upstream cooling chamber having a volume which is closed downstream by a permeable partition, and having a cooling gas inlet for receiving the cooling gas at a higher inlet pressure and for expanding the cooling gas downstream at a pressure lower than the higher inlet pressure,
wherein the system comprises:
the cooling gas driver being configured as either one of both a centralized and a distributed gas driving facility dedicated to provide a flow of treated cooling gas at a high-pressure differential through the cooling apparatus, the cooling gas driver being disposed remote and away from the cooling apparatus and from the heat generating device;
a plurality of orifices distributed within the permeable partition to permit gas flow from upstream to downstream thereof;
governing parameters of the cooling apparatus, of the partition and of the cooling gas driver being selected appropriately, and computing mutual operative matching to achieve optimal cooling in association with the heat generating device; and
an expanded cooling gas outlet being provided for exit of the heated cooling gas out of the cooling apparatus,
whereby the cooling gas is used to absorb heat from and transfer heat away from the heat-generating device.

12. The system according to claim 11, wherein:
the permeable partition has a plurality of orifices, where each orifice out of the plurality of orifices is shaped as an optimal aerodynamic nozzle allowing the cooling gas to expand therethrough;
an expansion chamber is disposed downstream of the permeable partition, which has a downstream surface that is separated at a predetermined distance away from the upstream surface of the heat-generating device, for the cooling gas directed to impinge upon and collect heat to cool the heat-generating device; and
the expanded cooling gas outlet entered in the expansion chamber has a predetermined size wherethrough the heated cooling gas controllably transfers heat away from the heat-generating device out of the cooling apparatus after having absorbed heat therefrom.

13. The system according to claim 11, wherein:
the permeable partition is implemented as a porous thermal conductor having an upstream face closing the cooling chamber, a downstream face abutting the heat-generating device, and sidewalls connecting the upstream face to the downstream face; and
the cooling gas expands via the pores to absorb heat collected by the thermal conductor from the heat generating device, and exits via the sidewalls to transfers heat out of the cooling apparatus and out of and away from the heat-generating device.

14. The system according to claim 13, wherein the volume of the upstream cooling chamber is reduced to nil.

15. The system according to claim 11, wherein the cooling gas driver is selected from the group consisting of facilities being centralized upstream, centralized downstream, and distributed upstream and downstream.

16. The system according to claim 11, wherein the cooling gas driver is selected alone and in combination from the group of cooling gas driver units consisting of compressing units, aspiration units, discharge turbines units, heat exchangers units, and ancillary units.

17. The system according to claim 11, wherein a same single haft couples different cooling gas driver units pertaining to a distributed cooling gas driver.

18. The system according to claim 11, wherein the cooling gas is selected as air.

19. The system according to claim 11, wherein the cooling gas driver is an integral portion of the integral cooling system, and is customized and configured to integrally match and fit for operative association in combination with the cooling apparatus, with the purpose of effectively and energy efficiently cooling the heat-generating device to desired controlled temperature levels, using minimizing energy consumption.

20. The system according to claim 11, wherein the cooling gas driver comprises a system for active sound suppression.
